(19) United States
(12) Patent Application Publication
(10) Pub. No.: US 2020/0139671 A1
(43) Pub. Date: May 7, 2020

(54) DISPLAY DEVICE AND ADHESION METHOD OF 3D COVER GLASS

(71) Applicant: Wuhan China Optoelectronics Semiconductor Display Technology Co., Ltd., Wuhan (CN)

(72) Inventor: Haoran CAO, Wuhan (CN)

(21) Appl. No.: 16/343,788

(22) PCT Filed: Aug. 2, 2018
(86) PCT No.: PCT/CN2018/098266

§ 371 Date: Apr. 22, 2019

(30) Foreign Application Priority Data
May 16, 2018 (CN) 201810466428.3

(51) Int. Cl. B32B 7/12; H05K 5/00; H05K 5/03; B32B 37/12

(52) U.S. Cl. CPC B32B 7/12; H05K 5/0017; B32B 2307/538; B32B 37/12; B32B 2457/20; H05K 5/03

(57) ABSTRACT

A display device and an adhesion method of 3D cover glass are provided. The display device includes a display panel, and a polarizer, a first OCA layer, a second OCA layer, and a 3D cover glass sequentially disposed on the display panel, where a stripping force between the 3D cover glass and the second OCA layer and a stripping force between the second OCA layer and the first OCA layer are the same, and both are greater than a stripping force between the first OCA layer and the polarizer.

### FIELD OF DISCLOSURE

The present disclosure relates to the field of display devices, and more particularly to a display device and an adhesion method of 3D cover glass.

### BACKGROUND

An outermost cover glass of a traditional mobile phone screen is flat (two-dimension, 2D), that is, all points on the glass are in the same plane. Then a 2.5D glass appears, where edges of the screen are rounded. Recently, a three-dimension (3D) cover glass has become a configuration of many high-end flexible OLED mobile phone screens. The 2D glass is deformed into the 3D cover glass by thermal bending.

In comparison to the 2.5D cover glass, the 3D cover glass has advantages such as better grip, more appealing to consumers, different design, and quick operation via a curved surface. However, the 3D cover glass has a significant drawback, it is easy to break when dropped, especially in the edge part with arc. At present, once the 3D cover glass is fragmented, an entire screen module should be replaced through a conventional adhesion process. The price of the screen module is usually ten times or more than the price of the 3D cover glass. However, in addition to the fragmented 3D cover, the screen module is still intact. Therefore, for a consumer, a maintenance cost will become higher.

The conventional 3D cover glass adhesion process is as shown in FIG. 1. A 3D cover glass 101 is adhered to an outermost surface of a screen 103 through an optically clear adhesive (OCA) 102. After adhering, it is subjected to high temperature and high pressure processing and passes a series of reliability tests. Therefore, it is difficult to rework after adhering. Even if the 3D cover glass 101 is forcibly separated from the screen 103 by heating, freezing, or the like, it can easily damage the screen 103.

Accordingly, it is necessary to provide a display device and an adhesion method of 3D cover glass to solve the technical problems in the prior art.

### SUMMARY OF THE DISCLOSURE

The present disclosure provides a display device and an adhesion method of 3D cover glass, which is easier to achieve separation of the cover glass after the cover glass is broken without damaging a screen, thereby changing a situation in which consumers can hardly carry out rework after traditional OCA adhesive is glued, and reducing a cost of use and maintenance for consumers.

In order to solve technical problems described above, the technical solution provided by the present disclosure is as follows.

The present disclosure provides an adhesion method of 3D cover glass, including:

step S1, providing a display panel which is to be adhered with the 3D cover glass, where a polarizer is attached to the display panel, and a first OCA (optically clear adhesive) layer is formed on the polarizer;

step S2, performing a viscosity enhancement treatment on a surface of the first OCA layer, where the surface is away from the polarizer;

step S3, forming a second OCA layer on the first OCA layer, and performing the viscosity enhancement treatment on surfaces of the second OCA layer, where one of the surfaces is in contact with the first OCA layer and the other surface is away from the first OCA layer; and

step S4, attaching the 3D cover glass on the second OCA layer.

According to one preferred embodiment of the present disclosure, an adhesion force between the 3D cover glass and the second OCA layer and an adhesion force between the second OCA layer and the first OCA layer are substantially the same, and both are greater than an adhesion force between the first OCA layer and the polarizer.

According to one preferred embodiment of the present disclosure, the step of performing the viscosity enhancement treatment on the surfaces of the first OCA layer and the second OCA layer including:

roughening a corresponding surface of the first OCA layer and corresponding surfaces of the second OCA layer.

According to one preferred embodiment of the present disclosure, the roughened surfaces of the first OCA layer and the second OCA layer are formed with regularly or irregularly distributed protrusions or recesses, and a form of cross-section of the protrusions include triangular, trapezoidal or rectangular forms.

According to one preferred embodiment of the present disclosure, a viscosity of the first OCA layer is less than a viscosity of the second OCA layer.

The present disclosure also provides a display device, including:

a display panel which is cell-assembled;

a polarizer disposed on a surface of the display panel;

a first OCA layer formed on the polarizer;

a second OCA layer formed on a surface of the first OCA layer; and

a 3D cover glass disposed on the second OCA layer,

wherein a stripping force between the 3D cover glass and the second OCA layer and a stripping force between the second OCA layer and the first OCA layer are substantially the same, and both are greater than a stripping force between the first OCA layer and the polarizer.

According to one preferred embodiment of the present disclosure, the roughnesses of two surfaces which the first OCA layer and the second OCA layer are adhered to each other and a roughness of the surface which the second OCA layer is adhered to the 3D cover glass are substantially the same, and both are greater than a roughness of the surface which the first OCA layer is adhered to the polarizer.

According to one preferred embodiment of the present disclosure, the two surfaces which the first OCA layer and the second OCA layer are adhered to each other and the surface which the second OCA layer is adhered to the 3D cover glass are formed with regularly or irregularly distributed protrusions or recesses.

According to one preferred embodiment of the present disclosure, a viscosity of the first OCA layer is less than a viscosity of the second OCA layer.

According to one preferred embodiment of the present disclosure, an ink protection layer is disposed at an edge position of the second OCA layer being adhered to the 3D cover glass.

The present disclosure also provides a display device, including:

a display panel which is cell-assembled;

a polarizer disposed on a surface of the display panel;

a first OCA layer formed on the polarizer;

a second OCA layer formed on a surface of the first OCA layer; and

a 3D cover glass disposed on the second OCA layer,

wherein a stripping force between the 3D cover glass and the second OCA layer and a stripping force between the second OCA layer and the first OCA layer are substantially the same, and both are greater than a stripping force between the first OCA layer and the polarizer, and a viscosity of the first OCA layer is less than a viscosity of the second OCA layer,

a surface of the first OCA layer in contact with the polarizer is substantially smooth.

According to one preferred embodiment of the present disclosure, the roughnesses of two surfaces which the first OCA layer and the second OCA layer are adhered to each other and a roughness of the surface which the second OCA layer is adhered to the 3D cover glass are substantially the same, and both are greater than a roughness of the surface which the first OCA layer is adhered to the polarizer.

According to one preferred embodiment of the present disclosure, the two surfaces which the first OCA layer and the second OCA layer are adhered to each other and the surface which the second OCA layer is adhered to the 3D cover glass are formed with regularly or irregularly distributed protrusions or recesses.

According to one preferred embodiment of the present disclosure, an ink protection layer is disposed at an edge position of the second OCA layer being adhered to the 3D cover glass.

The present disclosure has advantages as follows: in comparison to a method of adhering a display device to a cover glass in the prior art, in a display device and an adhesion method of 3D cover glass of the present disclosure, an OCA layer structure between the polarizer and the 3D cover glass is designed as a double-layer structure, and the roughness of surfaces of the double OCA layers is increased, such that the double OCA layers are more easily adhered to each other. Moreover, a viscosity enhancement treatment is performed on upper and lower surfaces of the second OCA layer so that the stripping force between the first OCA layer and the second OCA layer is approximately equal to the stripping force between the second OCA layer and the cover glass (i.e., the 3D cover glass), and the stripping force of both is greater than the stripping force between the first OCA layer and the polarizer (POL). Alternatively, by using OCAs with different viscosities to match the stripping force, when the cover glass is fragmented, it is easier to separate the first OCA layer from the polarizer without damaging the display screen during reworking.

### BRIEF DESCRIPTION OF THE DRAWINGS

In order to more clearly describe the technical solutions of the embodiments of the present disclosure, accompanying drawings to be used in the detailed description of the disclosure will be briefly described herein below. Obviously, the accompanying drawings described herein below only illustrate some of the embodiments of the present disclosure, and those of ordinary skill in the art can also obtain other accompanying drawings therefrom without the need of making inventive efforts.

FIG. 1 is a schematic diagram of an adhesion process of a 3D cover glass and a display panel in the prior art.

FIG. 2 is a flow chart of an adhesion method of 3D cover glass according to an embodiment of the present disclosure.

FIG. 3 is a structural diagram of an OCA layer according to an embodiment of the present disclosure.

FIG. 4 is a structural diagram of a display device according to an embodiment of the present invention.

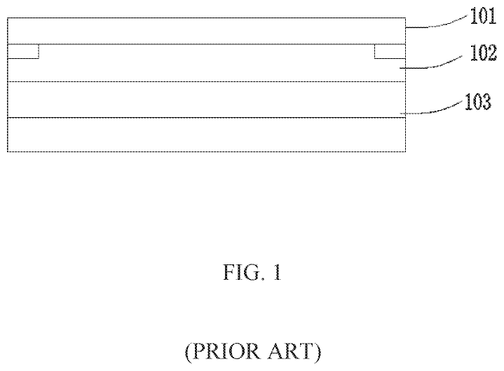

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

In the prior art method of adhering a display device to a cover glass, there is a technical problem that it is difficult to perform rework after the cover glass is broken, and a screen is easily damaged during the separation of the cover glass, thereby increasing a cost of use and maintenance for consumers. The present disclosure overcomes the aforementioned drawback.

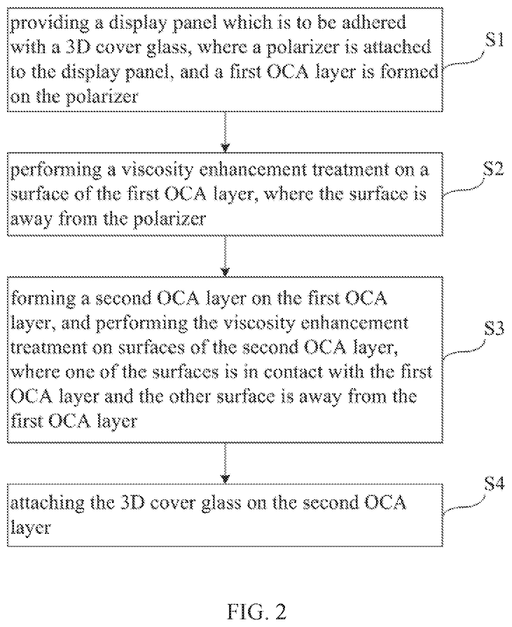

Referring to FIG. 2, which is a flow chart of an adhesion method of 3D cover glass according to an embodiment of the present disclosure. The method includes the following steps.

Step S1, a display panel which is to be adhered with the 3D cover glass is provided. A polarizer is attached to the display panel, and a first OCA (optically clear adhesive) layer is formed on the polarizer.

Step S2, a viscosity enhancement treatment is performed on a surface of the first OCA layer, where the surface is away from the polarizer.

Step S3, a second OCA layer is formed on the first OCA layer, and the viscosity enhancement treatment is performed on surfaces of the second OCA layer, where one of the surfaces is in contact with the first OCA layer and the other surface is away from the first OCA layer.

Step S4, the 3D cover glass is attached on the second OCA layer.

Specifically, the polarizer is attached on the display panel which is to be adhered with the 3D cover glass, and then OCA layers are formed through two processes. The first OCA layer is firstly formed on the polarizer. The viscosity enhancement treatment is performed on a surface of the first OCA layer, where the surface is away from the polarizer. Preferably, the method of the viscosity enhancement treatment is to roughen the surface of the first OCA layer, so that the surface of the first OCA layer undergoes a slight deformation to increase its roughness. The second OCA layer is sequentially formed on the first OCA layer. The viscosity enhancement treatment is performed on surfaces of the second OCA layer, where one of the surfaces is in contact with the first OCA layer and the other surface is away from the first OCA layer. The treating method is the same as the above method.

Please refer to FIG. 3, which is a structural diagram of an OCA layer according to an embodiment of the present disclosure. In FIG. 3, the second OCA layer 31 is disposed on the first OCA layer 30. A first surface 301 of the first OCA layer 30 in contact with the polarizer is substantially smooth. A second surface 302 of the first OCA layer 30 and a first surface 311 and a second surface 312 of the second OCA layer 31 are all roughened by roughening processes, thereby increasing the contact area, so that it is easier for the first OCA layer 30 and the second OCA layer 31 to be adhered to each other. Furthermore, the roughening treatment is performed on the upper and lower surfaces of the second OCA layer 31, which also makes it easier for the second OCA layer 31 and the 3D cover glass to be adhered to each other. An adhesion force between the 3D cover glass and the second OCA layer 31 and an adhesion force between the second OCA layer 31 and the first OCA layer 30 are substantially the same, and both are greater than an adhesion force between the first OCA layer 30 and the polarizer.

The second surface 302 of the first OCA layer 30 and the first surface 311 and the second surface 312 of the second OCA layer are formed with regularly or irregularly distributed protrusions 313 (or recesses). Preferably, a form of cross-section of the protrusions 313 includes triangular, trapezoidal, or rectangular forms. Preferably, head portions of the protrusions 313 are oriented in different directions. The shape of the protrusions 313 is not limited thereto. In addition, in the present disclosure, the adhesion force of the corresponding surfaces of the first OCA layer 30 and the second OCA layer 31 may be modified for achieving the above adhesion force match, which will not be described herein.

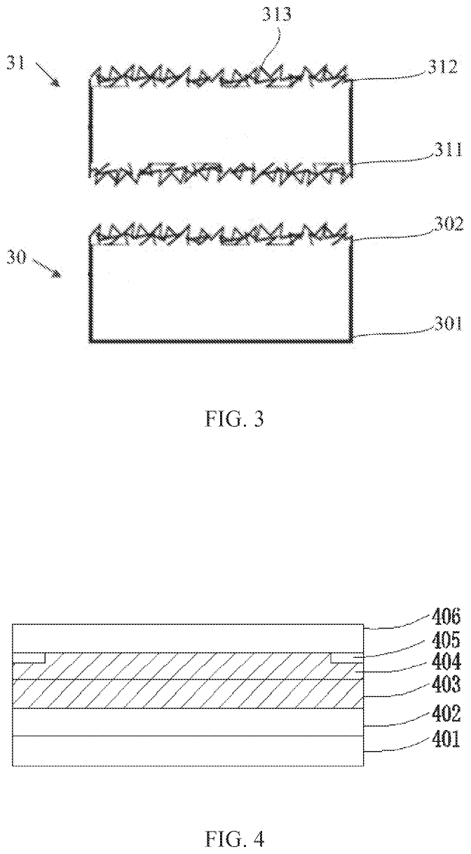

Please refer to FIG. 4, which is a structural diagram of a display device according to an embodiment of the present invention, including: a display panel 401 which is cell-assembled, a polarizer 402 disposed on a surface of the display panel 401, a first OCA layer 403 formed on the polarizer 402, a second OCA layer 404 formed on a surface of the first OCA layer 403, and an ink protection layer 405 disposed on a surface of the second OCA layer 404 away from the first OCA layer 403 and disposed at an edge position of the second OCA layer 404, and a 3D cover glass 406 disposed on the second OCA layer 404.

A stripping force between the 3D cover glass 406 and the second OCA layer 404 and a stripping force between the second OCA layer 404 and the first OCA layer 403 are substantially the same, and both are greater than a stripping force between the first OCA layer 403 and the polarizer 402. Preferably, the roughnesses of two surfaces which the first OCA layer 403 and the second OCA layer 404 are adhered to each other and a roughness of the surface which the second OCA layer 404 is adhered to the 3D cover glass 406 are substantially the same, and both are greater than a roughness of the surface which the first OCA layer 403 is adhered to the polarizer 402.

Preferably, the two surfaces which the first OCA layer 403 and the second OCA layer 404 are adhered to each other and the surface which the second OCA layer 404 is adhered to the 3D cover glass 406 are formed with regularly or irregularly distributed protrusions or recesses (as shown in FIG. 3).

Preferably, a viscosity of the first OCA layer 403 is less than a viscosity of the second OCA layer 404.

In addition, the first OCA layer 403 and the second OCA layer 404 may be the same type of OCA and combined into the same layer. A surface of the OCA layer adhered to the polarizer 402 is subjected to a viscosity reduction treatment, and a surface of the OCA layer adhered to the 3D cover glass 406 is subjected to a viscosity enhancement treatment. Alternatively, the viscosity of the OCA layer is in gradient distribution and is subjected to a corresponding treatment.

In comparison to a method of adhering a display device to a cover glass in the prior art, in a display device and an adhesion method of 3D cover glass of the present disclosure, an OCA layer structure between the polarizer and the 3D cover glass is designed as a double-layer structure, and the roughness of surfaces of the double OCA layers is increased, such that the double OCA layers are more easily adhered to each other. Moreover, a viscosity enhancement treatment is performed on upper and lower surfaces of the second OCA layer so that the stripping force between the first OCA layer and the second OCA layer is approximately equal to the stripping force between the second OCA layer and the cover glass (i.e., the 3D cover glass), and the stripping force of both is greater than the stripping force between the first OCA layer and the polarizer (POL). Alternatively, by using OCAs with different viscosities to match the stripping force, when the cover glass is fragmented, it is easier to separate the first OCA layer from the polarizer without damaging the display screen during reworking.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

1. An adhesion method of a three-dimension (3D) cover glass, comprising:
step S1, providing a display panel which is to be adhered with the 3D cover glass, wherein a polarizer is attached to the display panel, and a first optically clear adhesive (OCA) layer is formed on the polarizer;
step S2, performing a viscosity enhancement treatment on a surface of the first OCA layer, wherein the surface is away from the polarizer;
step S3, forming a second OCA layer on the first OCA layer, and performing the viscosity enhancement treatment on surfaces of the second OCA layer, wherein one of the surfaces is in contact with the first OCA layer and the other surface is away from the first OCA layer; and
step S4, attaching the 3D cover glass on the second OCA layer.

2. The adhesion method as claimed in claim 1, wherein an adhesion force between the 3D cover glass and the second OCA layer and an adhesion force between the second OCA layer and the first OCA layer are substantially the same, and both are greater than an adhesion force between the first OCA layer and the polarizer.

3. The adhesion method as claimed in claim 1, wherein the step of performing the viscosity enhancement treatment on the surfaces of the first OCA layer and the second OCA layer comprising:
roughening a corresponding surface of the first OCA layer and corresponding surfaces of the second OCA layer.

4. The adhesion method as claimed in claim 3, wherein the roughened surfaces of the first OCA layer and the second OCA layer are formed with regularly or irregularly distributed protrusions or recesses, and a form of cross-section of the protrusions comprise triangular, trapezoidal or rectangular forms.

5. The adhesion method as claimed in claim 1, wherein a viscosity of the first OCA layer is less than a viscosity of the second OCA layer.

6. A display device, comprising:
a display panel which is cell-assembled;
a polarizer disposed on a surface of the display panel;
a first OCA layer formed on the polarizer;
a second OCA layer formed on a surface of the first OCA layer; and
a 3D cover glass disposed on the second OCA layer,
wherein a stripping force between the 3D cover glass and the second OCA layer and a stripping force between the second OCA layer and the first OCA layer are substantially the same, and both are greater than a stripping force between the first OCA layer and the polarizer.

7. The display device as claimed in claim 6, wherein the roughnesses of two surfaces which the first OCA layer and the second OCA layer are adhered to each other and a roughness of the surface which the second OCA layer is adhered to the 3D cover glass are substantially the same, and both are greater than a roughness of the surface which the first OCA layer is adhered to the polarizer.

8. The display device as claimed in claim 7, wherein the two surfaces which the first OCA layer and the second OCA layer are adhered to each other and the surface which the second OCA layer is adhered to the 3D cover glass are formed with regularly or irregularly distributed protrusions or recesses.

9. The display device as claimed in claim 6, wherein a viscosity of the first OCA layer is less than a viscosity of the second OCA layer.

10. The display device as claimed in claim 6, wherein an ink protection layer is disposed at an edge position of the second OCA layer being adhered to the 3D cover glass.

11. A display device, comprising:
a display panel which is cell-assembled;
a polarizer disposed on a surface of the display panel;
a first OCA layer formed on the polarizer;
a second OCA layer formed on a surface of the first OCA layer; and
a 3D cover glass disposed on the second OCA layer,
wherein a stripping force between the 3D cover glass and the second OCA layer and a stripping force between the second OCA layer and the first OCA layer are substantially the same, and both are greater than a stripping force between the first OCA layer and the polarizer, and a viscosity of the first OCA layer is less than a viscosity of the second OCA layer,
wherein a surface of the first OCA layer in contact with the polarizer is substantially smooth.

12. The display device as claimed in claim 11, wherein the roughnesses of two surfaces which the first OCA layer and the second OCA layer are adhered to each other and a roughness of the surface which the second OCA layer is adhered to the 3D cover glass are substantially the same, and both are greater than a roughness of the surface which the first OCA layer is adhered to the polarizer.

13. The display device as claimed in claim 12, wherein the two surfaces which the first OCA layer and the second OCA layer are adhered to each other and the surface which the second OCA layer is adhered to the 3D cover glass are formed with regularly or irregularly distributed protrusions or recesses.

14. The display device as claimed in claim 11, wherein an ink protection layer is disposed at an edge position of the second OCA layer being adhered to the 3D cover glass.
